(19) United States
(12) Patent Application Publication
(10) Pub. No.: US 2025/0301861 A1
(43) Pub. Date: Sep. 25, 2025

(54) DISPLAY PANEL

(71) Applicant: Hefei Visionox Technology Co., Ltd., Hefei (CN)

(72) Inventors: Hongyan XUE, Hefei (CN); Hui LI, Hefei (CN); Min ZOU, Hefei (CN)

(73) Assignee: Hefei Visionox Technology Co., Ltd., Hefei (CN)

(21) Appl. No.: 19/228,655

(22) Filed: Jun. 4, 2025

(30) Foreign Application Priority Data
Jun. 7, 2024 (CN) 202410740584.X

(51) Int. Cl. H10K 59/122; H10K 59/38; H10K 59/80

(52) U.S. Cl. CPC H10K 59/122; H10K 59/38; H10K 59/8792

(57) ABSTRACT

An embodiment of the present application provides a display panel, including: a substrate; and a pixel defining layer arranged on the substrate, the pixel defining layer including a pixel defining portion and a plurality of pixel openings enclosed by the pixel defining portion, where the pixel defining portion includes an inner wall surface facing at least one of the pixel openings, a cross section of the inner wall surface in a thickness direction of the display panel includes a plurality of arc segments sequentially connected to each other in a direction away from the substrate, and among at least two adjacent arc segments, an included angle between the arc segment closer to the substrate and a light exit surface of the display panel is greater than an included angle between the arc segment farther from the substrate and the light exit surface of the display panel.

### CROSS-REFERENCE TO RELATED APPLICATIONS

The present application claims priority to the Chinese Patent Application No. 202410740584.X, filed on Jun. 7, 2024, and the entire contents of the aforementioned application are hereby incorporated by reference in its entirety.

### FIELD

The present application relates to the field of display equipment, and particularly to a display panel.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the use performance of conventional OLED display products needs to be improved.

### SUMMARY

Embodiments of the present application provide a display panel and a display device, with the aim of improving the use performance of the display panel.

An embodiment of a first aspect of the present application provides a display panel, including: a substrate; and a pixel defining layer arranged on the substrate, the pixel defining layer including a pixel defining portion and a plurality of pixel openings enclosed by the pixel defining portion, where the pixel defining portion includes an inner wall surface facing at least one of the pixel openings, a cross section of the inner wall surface in a thickness direction of the display panel includes a plurality of arc segments sequentially connected to each other in a direction away from the substrate, and among at least two adjacent arc segments, an included angle between the arc segment closer to the substrate and a light exit surface of the display panel is greater than an included angle between the arc segment farther from the substrate and the light exit surface of the display panel; and the included angle between the arc segment and the light exit surface of the display panel opens toward the corresponding pixel defining portion.

According to any one of the above implementations of the first aspect of the present application, the included angle between each arc segment and the light exit surface of the display panel is in a value range of 27° to 33°.

According to any one of the above implementations of the first aspect of the present application, three or more arc segments are provided.

According to any one of the above implementations of the first aspect of the present application, five arc segments are provided.

According to any one of the above implementations of the first aspect of the present application, the included angles between the arc segments of the pixel defining layer and the light exit surface of the display panel gradually decrease in the direction away from the substrate.

According to any one of the above implementations of the first aspect of the present application, each arc segment is in the shape of a circular arc;
and/or the pixel defining portion has the inner wall surface facing each of the pixel openings.

According to any one of the above implementations of the first aspect of the present application, an orthographic projection of the pixel opening on the substrate is located within an orthographic projection of a light shielding opening on the substrate.

According to any one of the above implementations of the first aspect of the present application, the edge of an orthographic projection of the filter portion on the substrate is enclosed by the plurality of arc-shaped segments connected in sequence, and/or the edge of the orthographic projection of the filter portion on the substrate includes a plurality of segments, two adjacent segments being connected with a smooth transition by means of the arc-shaped segment.

According to any one of the above implementations of the first aspect of the present application, a first side and a second side are arc-shaped segments, and/or the first side and the second side are connected with a smooth transition by means of the arc-shaped segment.

An embodiment of the first aspect of the present application further provides a display panel, including: a substrate; and a pixel defining layer arranged on the substrate, the pixel defining layer including a pixel defining portion and a plurality of pixel openings enclosed by the pixel defining portion,
where the pixel defining portion includes an inner wall surface facing at least one of the pixel openings, a cross section of the inner wall surface in a thickness direction includes a curve segment, and an included angle between the curve segment and a light exit surface of the display panel ranges from 25° to 35°.

According to an implementation of the first aspect of the present application, the curve segment has a plurality of arc segments.

According to any one of the above implementations of the first aspect of the present application, among any two adjacent arc segments of the plurality of arc segments, an included angle between the arc segment closer to the substrate and the light exit surface of the display panel is greater than an included angle between the arc segment farther from the substrate and the light exit surface of the display panel.

According to any one of the above implementations of the first aspect of the present application, the included angle between each arc segment and the light exit surface of the display panel ranges from 25° to 35°. According to any one of the above implementations of the first aspect of the present application, the included angle between each arc segment and the light exit surface of the display panel is in a value range of 27° to 33°.

According to any one of the above implementations of the first aspect of the present application, the display panel further includes: a filter layer located on a side of the pixel defining layer facing away from the substrate, the filter layer including a plurality of filter portions, where an edge of an orthographic projection of the filter portion on the substrate includes one or more arc-shaped segments.

According to any one of the above implementations of the first aspect of the present application, the edge of the orthographic projection of the filter portion on the substrate is enclosed by the plurality of arc-shaped segments connected in sequence, and/or the edge of the orthographic projection of the filter portion on the substrate includes a plurality of segments, two adjacent segments being connected with a smooth transition by means of the arc-shaped segment.

An embodiment of the first aspect of the present application further provides a display panel, including: a substrate; and a filter layer located on one side of the substrate, the filter layer including a plurality of filter portions, an edge of an orthographic projection of at least one filter portion on the substrate being enclosed by a plurality of arc-shaped segments connected in sequence.

According to any one of the above implementations of the first aspect of the present application, a first side and a second side are arc-shaped segments, and the first side and the second side are connected with a smooth transition by means of the arc-shaped segment.

According to any one of the above implementations of the first aspect of the present application, the plurality of filter portions further include second filter portions and third filter portions, a plurality of second filter portions and a plurality of third filter portions being alternately distributed on a circumferential side of the first filter portion, the first side facing the second filter portion, and the second side facing the third filter portion.

According to any one of the above implementations of the first aspect of the present application, the first side and the second side are recessed toward a filter area, and a transition side is connected between the first side and the second side, the transition side protruding in a direction away from the filter area.

According to any one of the above implementations of the first aspect of the present application, at least part of a diffusion area of the first filter portion is located between two adjacent other filter portions.

According to an implementation of the first aspect of the present application, at least part of the diffusion area is located between adjacent second filter portions.

According to an implementation of the first aspect of the present application, four second filter portions and four third filter portions are alternately distributed on the circumferential side of the first filter portion, and the diffusion area includes four first diffusion sub-areas surrounding a circumferential side of the filter area, each first diffusion sub-area extending from the filter area toward the third filter portion, and at least part of each first diffusion sub-area being located between two adjacent second filter portions.

According to an implementation of the first aspect of the present application, the first filter portion is a red filter portion, the second filter portion is a green filter portion, and the third filter portion is a blue filter portion.

According to an implementation of the first aspect of the present application, the display panel further includes a pixel defining layer arranged between the substrate and the filter layer, the pixel defining layer including a pixel defining portion and a plurality of pixel openings enclosed by the pixel defining portion.

According to an implementation of the first aspect of the present application, the pixel defining portion includes an inner wall surface facing at least one of the pixel openings, a cross section of the inner wall surface in a thickness direction of the display panel includes the cross section in the thickness direction includes a curve segment, and an included angle between the curve segment and a light exit surface of the display panel is in a value range of 25° to 35°.

According to an implementation of the first aspect of the present application, the curve segment includes a plurality of arc segments connected in sequence in a direction away from the substrate,
where among at least two adjacent arc segments, an included angle between the arc segment closer to the substrate and the light exit surface of the display panel is greater than an included angle between the arc segment farther from the substrate and the light exit surface of the display panel.

An embodiment of the first aspect of the present application further provides a display panel, including:
a substrate according to the implementations of the first aspect of the present application; and a filter layer located on one side of the substrate, the filter layer including a plurality of filter portions, where an edge of an orthographic projection of at least one of the filter portions on the substrate includes a plurality of segments, two adjacent segments being connected with a smooth transition by means of an arc-shaped segment.

According to an implementation of the first aspect of the present application, the display panel further includes a pixel defining layer arranged between the substrate and the filter layer, the pixel defining layer including a pixel defining portion and a plurality of pixel openings enclosed by the pixel defining portion.

According to an implementation of the first aspect of the present application, the pixel defining portion includes an inner wall surface facing at least one of the pixel openings, a cross section of the inner wall surface in a thickness direction of the display panel includes the cross section in the thickness direction includes a curve segment, and an included angle between the curve segment and a light exit surface of the display panel is in a value range of 25° to 35°.

According to an implementation of the first aspect of the present application, the curve segment includes a plurality of arc segments connected in sequence in a direction away from the substrate,
where among at least two adjacent arc segments, an included angle between the arc segment closer to the substrate and the light exit surface of the display panel is greater than an included angle between the arc segment farther from the substrate and the light exit surface of the display panel.

An embodiment of a second aspect of the present application further provides a display device, including a display panel according to any one of the above embodiments of the first aspect.

According to the display panel provided in the embodiments of the present application, the display panel includes the substrate and the pixel defining layer arranged on the substrate, the pixel defining layer including the pixel defining portion and the pixel openings, where the pixel openings may be configured to receive light-emitting units. By providing the pixel defining portion and the pixel openings, the problem of mutual interference between two adjacent light-emitting units during light emission can be alleviated. The cross section of the inner wall surface of the pixel defining portion facing at least one of the pixel openings includes the plurality of arc segments, and the shape of the inner wall surface is made smoother to facilitate the falling of a material of the light-emitting unit into the pixel opening; and during subsequent fabrication of an electrode, a conductive material is less prone to breakage at the inner wall surface, so that the yield of the electrode can be improved. In addition, since the included angle between the arc segment closer to the substrate and the light exit surface of the display panel is greater than the included angle between the arc segment farther from the substrate and the light exit surface, when light reflected from the electrode in the pixel opening reaches the inner wall surface and is reflected by the inner wall surface, a light exit angle of the light reflected from the inner wall surface can be decreased, the display effect of the display panel can then be improved, and the use performance of the display panel can thus be improved.

### BRIEF DESCRIPTION OF THE DRAWINGS

By reading the following detailed description made with reference to the drawings for non-limiting embodiments, the other features, objectives and advantages of the present application will become more apparent, in which the same or similar features are denoted by the same or similar reference numerals.

FIG. 1 is a structural schematic view of a display panel according to an embodiment of the present application;

FIG. 2 is a structural schematic partial enlarged view of part P of FIG. 1 in an example;

FIG. 3 is a partial cross-sectional view taken along line C-C in FIG. 2;

FIG. 4 is a structural schematic partial enlarged view of FIG. 3;

FIG. 5 is a structural schematic partial enlarged view of part P of FIG. 1 in another example;

FIG. 6 is a partial cross-sectional view taken along line D-D in FIG. 5;

FIG. 7 is a structural schematic partial enlarged view of FIG. 5;

FIG. 8 is a structural schematic partial enlarged view of FIG. 7 in an example;

FIG. 9 is a structural schematic partial enlarged view of FIG. 7 in another example;

FIG. 10 is a structural schematic partial enlarged view of FIG. 7 in still another example;

FIG. 11 is a structural schematic view of a display panel of the related art in an active state;

FIG. 12 is a structural schematic view of a display panel according to an embodiment of the present application in an active state;

FIG. 13 is another structural schematic view of a display panel of the related art in an active state;

FIG. 14 is another structural schematic view of a display panel according to an embodiment of the present application in an active state; and

FIG. 15 is a structural schematic view of a display device according to an embodiment of the present application.

### DETAILED DESCRIPTION OF THE EMBODIMENTS

The features and exemplary embodiments of the present application in various aspects will be described in detail below. In the following detailed description, many specific details are set forth to comprehensively understand the present application. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures or characteristics described below may be combined, in any suitable manner, in one or more embodiments.

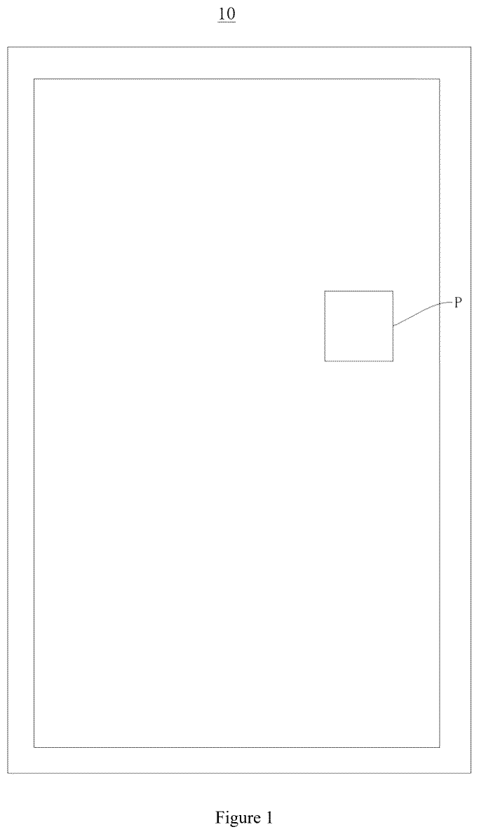

In order to better understand the present application, a display panel and a display device according to the embodiments of the present application will be described in detail below with reference to FIGS. 1 to 14.

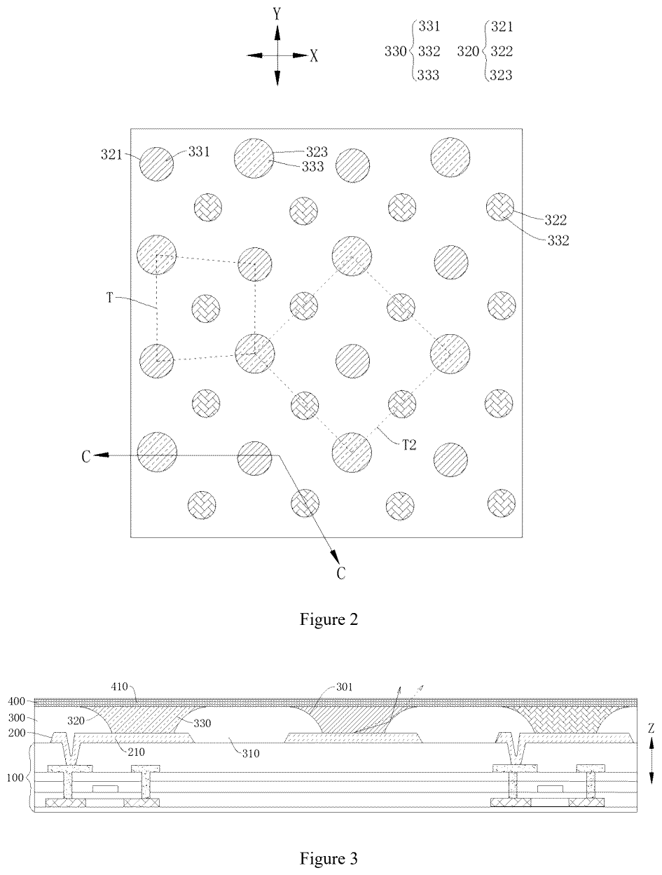

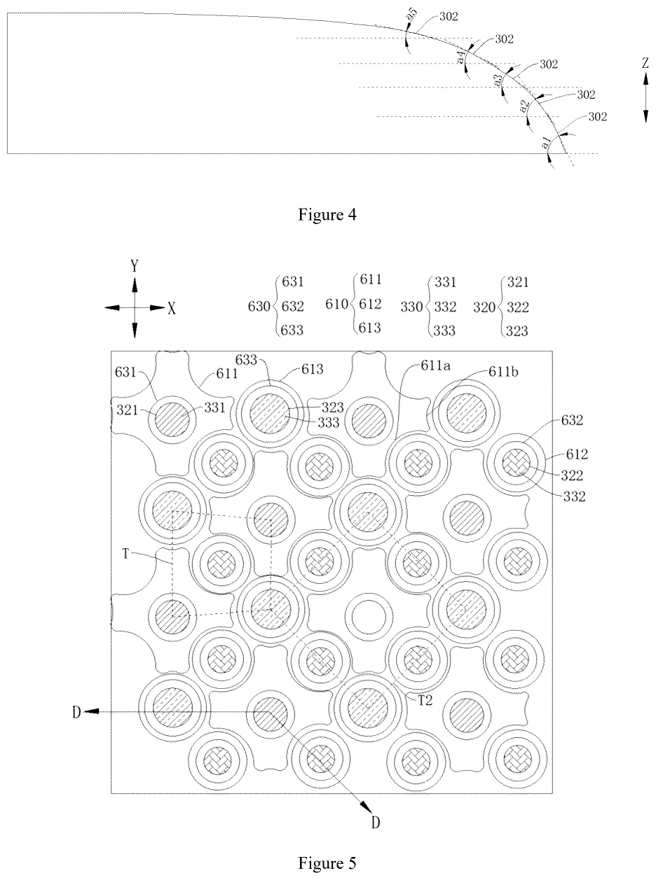

Referring to FIGS. 1 to 4 together, FIG. 1 is a structural schematic view of a display panel 10 according to an embodiment of the present application, FIG. 2 is a structural schematic partial enlarged view of part P of FIG. 1 in an example, FIG. 3 is a cross-sectional view taken along line C-C in FIG. 2, and FIG. 4 is a structural schematic partial enlarged view of FIG. 3.

As shown in FIGS. 1 to 4, the display panel 10 includes a substrate 100 and a pixel defining layer 300. The pixel defining layer 300 is arranged on one side of the substrate 100, and the pixel defining layer 300 includes a pixel defining portion 310 and pixel openings 320 enclosed by the pixel defining portion 310. A plurality of pixel openings 320 are provided. The pixel defining portion 310 includes an inner wall surface 301 facing at least one of the pixel openings 320, a cross section of the inner wall surface 301 in a thickness direction of the display panel 10 includes a plurality of arc segments 302 sequentially connected in a direction away from the substrate 100, and among at least two adjacent arc segments 302, an included angle between the arc segment 302 closer to the substrate 100 and a light exit surface of the display panel 10 is greater than an included angle between the arc segment 302 farther from the substrate 100 and the light exit surface of the display panel 10.

FIG. 4 illustrates a structural schematic partial enlarged view of the inner wall surface 301 of the pixel defining portion 310. As shown in FIG. 4, the inner wall surface 301 of the inner wall surface 301 in the thickness direction includes the plurality of arc segments 302 connected in sequence. As shown in FIG. 4, for example, among two adjacent arc segments 302, the included angle between the arc segment 302 closer to the substrate 100 and the light exit surface of the display panel 10 is represented by a1, and the included angle between the arc segment 302 closer to the substrate 100 and the light exit surface of the display panel 10 is represented by a2, where a1 is greater than a2.

According to the display panel 10 provided in the embodiments of the present application, the display panel 10 includes the substrate 100 and the pixel defining layer 300 arranged on the substrate 100, the pixel defining layer 300 including the pixel defining portion 310 and the pixel openings 320, where the pixel openings 320 may be configured to receive light-emitting units 330. By providing the pixel defining portion 310 and the pixel openings 320, the problem of mutual interference between two adjacent light-emitting units 330 during light emission can be alleviated. The cross section of the inner wall surface 301 of the pixel defining portion 310 facing at least one of the pixel openings 320 includes the plurality of arc segments 302, and the shape of the inner wall surface 301 is made smoother to facilitate the falling of a material of the light-emitting unit 330 into the pixel opening 320; and during subsequent fabrication of an electrode, a conductive material is less prone to breakage at the inner wall surface 301, so that the yield of the electrode can be improved. In addition, since the included angle between the arc segment 302 closer to the substrate 100 and the light exit surface of the display panel 10 is greater than the included angle between the arc segment 302 farther from the substrate 100 and the light exit surface, when light reflected from the electrode in the pixel opening 320 reaches the inner wall surface 301 and is reflected by the inner wall surface 301, a light exit angle of the light reflected from the inner wall surface 301 can be decreased, a diffraction effect can be improved, the display effect of the display panel 10 can then be improved, and the use performance of the display panel 10 can thus be improved.

The thickness direction Z of the display panel 10 is a direction in which the substrate 100 and the pixel defining layer 300 are stacked. The light exit surface of the display panel 10 is perpendicular to the thickness direction Z. The larger the included angle between the exit light and the light exit surface of the display panel 10, the more the light exit in a forward direction, and the better the forward display effect of the display panel 10.

In an embodiment, the included angle between the arc segment 302 and the light exit surface of the display panel 10 may be an included angle between a tangent line of the arc segment 302 and the light exit surface of the display panel 10, and the included angle opens toward the corresponding pixel defining portion 310. The plurality of arc segments 302 have different curvatures and positions, resulting in different included angles between different arc segments 302 and the light exit surface. According to the embodiments of the present application, among at least two adjacent arc segments 302, the included angle between the tangent line of the arc segment 302 closer to the substrate 100 and the light exit surface is greater than the included angle between the tangent line of the arc segment 302 farther from the substrate 100 and the light exit surface. The arc segment 302 protrudes toward the corresponding pixel opening 320.

The substrate 100 may be configured in a variety of ways. The substrate 100 may include a base substrate, and a first conductive layer, a second conductive layer and a third conductive layer that are arranged on one side of the substrate in a stacked manner. An insulating layer is arranged between adjacent conductive layers. In an embodiment, a drive device layer is arranged on the base substrate, and a pixel driving circuit is arranged in the drive device layer and includes a transistor and a storage capacitor. The transistor includes a semiconductor, a gate, a source and a drain. The storage capacitor includes a first plate and a second plate. As an example, the gate and the first plate may be located in the first conductive layer, the second plate may be located in the second conductive layer, and the source and the drain may be located in the third conductive layer.

In an embodiment, a first electrode layer 200 is arranged on the substrate 100. The first electrode layer 200 includes a plurality of first electrodes 210 distributed at intervals, and an orthographic projection of each pixel opening 320 on the substrate 100 at least partially overlaps with an orthographic projection of a respective first electrode 210 on the substrate 100, and the first electrode 210 can be partially exposed from the pixel opening 320 and then in direct contact connection with the light-emitting units 330 in the pixel opening 320, and the first electrode 210 transmits an electrical signal to the light-emitting unit 330. In an embodiment, the light-emitting unit 330 is arranged in the pixel opening 320, and the display panel 10 further includes a second electrode layer 400. The second electrode layer 400 includes second electrodes 410 located on a side of the light-emitting unit 330 facing away from the substrate 100. The second electrodes 410 may be interconnected to for a surface electrode. One of the first electrode 210 and the second electrode 410 is an anode, and the other is a cathode. An embodiment of the present application is exemplified by using the first electrode 210 as the anode and the second electrode 410 as the cathode.

In an embodiment, the first electrode 210 is a reflective electrode, and the second electrode 410 is a transparent electrode. A material of the first electrode 210 typically includes a conductive metal material. As a result, the first electrode 210 reflects the light incident from the pixel opening 320. The light reflected at a large angle by the first electrode 210 is reflected to the inner wall surface 301 and is then reflected out from the inner wall surface 301. The inventors have found that when the angle of the light reflected from the inner wall surface 301 is excessively large, a pronounced circular diffraction ring may be formed on a circumferential side of the pixel opening 320. Moreover, the smaller a distance between the part of the inner wall surface 301 closer to the substrate 100 and the first electrode 210, the larger the amount of the light reflected therefrom.

In the embodiments of the present application, among at least two adjacent arc segments 302, the included angle between the arc segment 302 closer to the substrate 100 and the light exit surface of the display panel 10 is greater than the included angle between the arc segment 302 farther from the substrate 100 and the light exit surface. In this way, in a direction close to the substrate 100, the angle of the light reflected from the inner wall surface 301 and the included angle in the thickness direction become smaller and smaller. The closer to the substrate 100, the more light is reflected by the inner wall surface 301, and thus the amount of the light reflected at a large angle from the inner wall surface 301 becomes smaller and smaller, so that the embodiments of the present application can alleviate the problem of the reflected light concentratedly exiting from the circumferential side of the pixel opening 320 to form the pronounced circular diffraction ring, and thus improve the display effect of the display panel 10.

In an embodiment, a plurality of pixel openings 320 are provided, and the pixel defining portion 310 has an inner wall surface 301 as described above facing one of the pixel openings 320. In one embodiment, the pixel defining portion 310 has an inner wall surface 301 as described above facing each of the plurality of pixel openings 320, to alleviate the problem of circular diffraction rings being likely to be formed on the circumferential sides of the plurality of pixel openings 320, that is, each of the pixel openings 320 is provided with the inner wall surface 301. In an embodiment, the pixel defining portion 310 has the inner wall surface 301 facing each pixel opening 320 to better improve the display effect of the display panel 10.

The arc segment 302 may be configured in a variety of ways, and the arc segment 302 may be part of an ellipse or a circle. For example, the arc segment 302 is in the shape of a circular arc to simplify the shape of the inner wall surface 301 and facilitate the fabrication and formation of the inner wall surface 301.

In some embodiments, the included angle between each arc segment 302 and the light exit surface is in a value range of 25° to 35°, that is, an included angle between a tangent line of each arc segment 302 and the light exit surface is in the value range of 25° to 35°. For example, the value of the included angle between the tangent line of each arc segment 302 and the light exit surface is 25°, 25.5°, 26°, 26.2°, 27°, 28°, 29°, 32°, 33°, 34.8°, 35°, etc.

In these embodiments, when the included angle between each arc segment 302 and the light exit surface is in the above value range, it is possible to alleviate the problem of, during subsequent fabrication of an encapsulation layer 500, pits being formed on the encapsulation layer 500 at the locations of the pixel openings 320 due to the excessively small included angle between the inner wall surface 301 and the thickness direction which otherwise affect the flatness of other film layers. It also possible to alleviate the problem of an excessively large exit angle of the light reflected from the inner wall surface 301 resulting in a pronounced circular diffraction ring on the circumferential side of the pixel opening 320 due to the excessively large included angle between each arc segment 302 and the thickness direction.

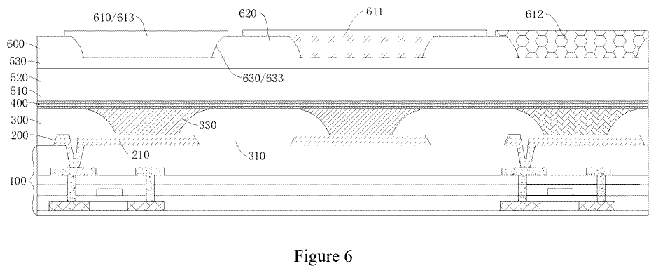

In an embodiment, referring to FIGS. 5 and 6 together, the display panel 10 further includes an encapsulation layer located on a side of the second electrode layer 400 facing away from the substrate 100. In an embodiment, the encapsulation layer includes a first encapsulation layer 510, a second encapsulation layer 520 and a third encapsulation layer 530. Materials of the first encapsulation layer 510 and the third encapsulation layer 530 may include an inorganic material to improve the compactness of the encapsulation layer 500. A material of the second encapsulation layer 520 includes an organic material to adjust the degree of planarization of the encapsulation layer 500.

In an embodiment, the display panel 10 further includes a filter layer 600. The filter layer 600 is located on a side of the encapsulation layer 500 facing away from the substrate 100, and the filter layer 600 includes a plurality of filter portions 610. An orthographic projection of each filter portion 610 on the substrate 100 at least partially overlaps with an orthographic projection of a respective pixel opening 320 on the substrate 100, and the filter portion 610 is configured to pass light within a designated wave band and filter light within other wave bands in order to improve the display effect of the display panel 10.

In an embodiment, the filter layer 600 and the encapsulation layer may further be provided with other film layers, such as a touch layer. In one embodiment, the filter layer 600 is in direct contact connection with the encapsulation layer.

When the included angle between each arc segment 302 and the light exit surface is excessively large, for example, when the included angle between each arc segment 302 and the thickness direction Z is less than 25°, for example when the included angle between each arc segment 302 and the thickness direction Z is 10°, 20° or 23°, that is, the included angle between each arc segment 302 and the light exit surface is greater than 75°, the inner wall surface 301 has a relatively large slope, resulting in that it is unlikely to fill the pits formed by the pixel openings 320 with the second encapsulation layer 520, and a surface of the second encapsulation layer 520 facing away from the substrate 100 is uneven, which may cause the filter portions 610 to be arranged on the uneven surface, thereby affecting the filtering effect of the filter portions 610. The thickness direction Z is a direction in which the substrate 100 and the pixel defining layer 300 are stacked. Moreover, when the included angle between each arc segment 302 and the thickness direction Z is excessive large and the inner wall surface 301 has a relatively small slope, the inner wall surface 301 becomes flatter, but the light reflected from the inner wall surface 301 has an excessively large light exit angle, the reflected light is gathered on the circumferential side of the pixel opening 320 and is thus prone to forming a pronounced circular diffraction ring, affecting the display effect of the display panel 10. In an embodiment of the present application, when the included angle between each arc segment 302 and the light exit surface ranges from 25° to 35°, the problem of unevenness of the encapsulation layer can be alleviated, and the problem of the circular diffraction ring can also be alleviated.

In an embodiment, the included angle between each arc segment 302 and the light exit surface is in a value range of 27° to 33° to better improve the display effect of the display panel 10.

The number of arc segments 302 may be set in a variety of ways, for example, two arc segments 302 are provided. In some embodiments, three or more arc segments 302 are provided. By providing a plurality of arc segments 302, the inner wall surface 301 varies more diversely, thereby better improving the display effect. As an embodiment, as shown in FIG. 4, five arc segments 302 may be provided, and the inner wall surface 301 also has a relatively simple shape while better improving the display effect, which facilitates the fabrication and formation.

When three or more arc segments 302 are provided, In an embodiment, among any adjacent arc segments 302 of the plurality of arc segments 302, the included angle between the arc segment 302 closer to the substrate 100 and the light exit surface is greater than the included angle between the arc segment 302 farther from the substrate 100 and the light exit surface, to better improve the display effect of the display panel 10. As shown in FIG. 4, in the direction away from the substrate 100, the included angles between the five arc segments 302 and the light exit surface are respectively represented by a1, a2, a3, a4 and a5, where a1>a2>a3>a4>a5.

In an embodiment, in the direction away from the substrate 100, the included angles between the arc segments 302 of the pixel defining layer 300 and the light exit surface gradually decrease and the pixel openings 320 are gradually enlarged and the pixel defining layer 300 is gradually flat in the direction away from the substrate 100.

In some embodiments, as described above, as shown in FIGS. 1 to 7, the display panel 10 further includes a filter layer 600. The filter layer 600 is located on a side of the pixel defining layer 300 facing away from the substrate 100, and the filter layer 600 includes a plurality of filter portions 610. An edge of an orthographic projection of at least one filter portion 610 on the substrate 100 includes one or more arc-shaped segments 601.

In these embodiments, the edge of the orthographic projection of the filter portion 610 on the substrate 100 includes the arc-shaped segments 601, and the shape of the orthographic projection of the filter portion 610 on the substrate 100 is made smoother, the light is unlikely to form pronounced diffraction starbursts in this region, and the display effect of the display panel 10 can be further improved.

For the filter portion 610, orthographic projections, on the substrate 100, of a surface thereof facing away from the substrate 100 and a surface thereof facing the substrate 100 have substantially the same shape, but the projections of the surfaces have different shapes only due to a CF material. Therefore, in the present application, the edge of the orthographic projection of the filter portion 610 on the substrate 100 may be an edge of the orthographic projection, on the substrate 100, of the surface of the filter portion 610 facing away from the substrate 100, or may be an edge of the orthographic projection, on the substrate 100, of the surface of the filter portion 610 facing the substrate 100.

In an embodiment, the edge of the orthographic projection of each of the plurality of filter portions 610 on the substrate 100 includes one or more arc-shaped segments 601.

In an embodiment, the filter layer 600 further includes a light shielding portion 620 and a light shielding opening 630 formed at the light shielding portion 620. At least part of the filter portion 610 is located at the light shielding opening 630. The light shielding portion 620 is configured to alleviate the problem of light crosstalk between two adjacent light shielding openings 630. In an embodiment, the orthographic projection of the pixel opening 320 on the substrate 100 is located within an orthographic projection of the light shielding opening 630 on the substrate 100 to improve the light output effect of the display panel 10 when the light shielding portion 620 shields the pixel opening 320.

In an embodiment, the orthographic projection of the light shielding openings 630 on the substrate 100 is located within the orthographic projection of the filter portion 610 on the substrate 100, and the entire light shielding opening 630 can be filled with the filter portion 610 to improve the filtering effect.

In an embodiment, the filter portion 610 covers at least part of a surface of the light shielding portion 620 facing away from the substrate 100, that is, part of the filter portion 610 is located on a side of the light shielding portion 620 facing away from the substrate 100. When a protective layer is subsequently arranged on the side of the light shielding portion 620 facing away from the substrate 100, the light shielding portion 620 is in contact with the protective layer, with an interface between the two, and has a certain light reflecting capability at the interface. According to the present application, by covering the filter portion 610 with the light shielding portion 620, the ability to reflect ambient light can be improved, the influence of the ambient light on the display effect can be reduced, and the display effect can further be improved.

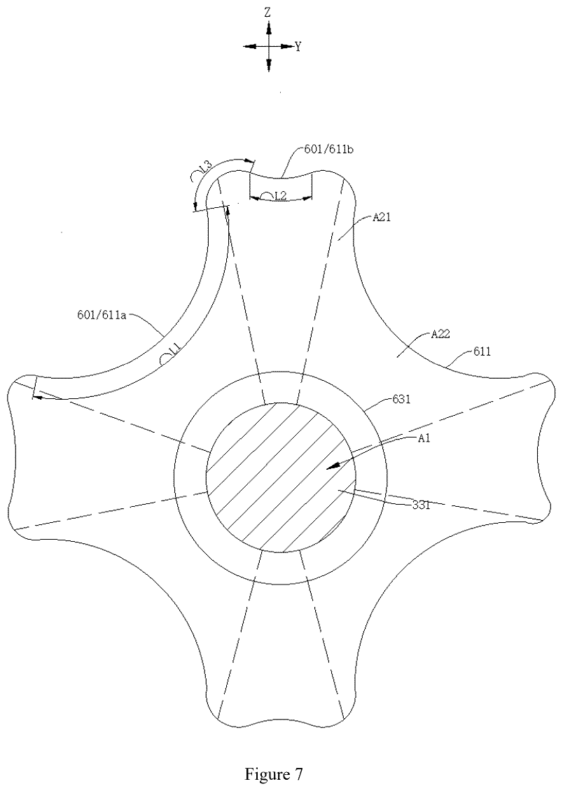

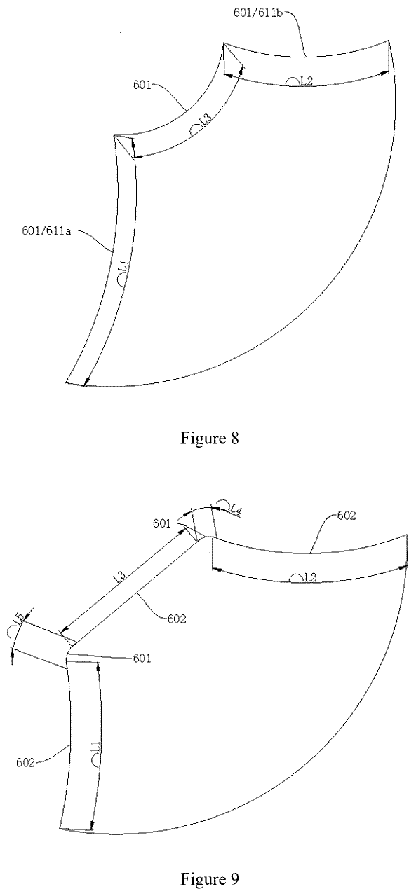

The orthographic projection of the filter portion 610 on the substrate 100 may be shaped in a variety of ways, for example, as shown in FIGS. 7 and 8, the orthographic projection of the filter portion 610 on the substrate 100 is enclosed by a plurality of arc-shaped segments 601 in sequence, that is, an edge of the orthographic projection of the filter portion 610 on the substrate 100 has no straight line segment, so that the problem of diffraction between adjacent light shielding portions 620 can be alleviated.

In some other embodiments, as shown in FIG. 9, the edge of the orthographic projection of the filter portion 610 on the substrate 100 includes a plurality of segments 602, two adjacent segments of the segments 602 being connected with a smooth transition by means of an arc-shaped segment 601.

When there is a sharp corner at the edge of the orthographic projection of the filter portion 610 on the substrate 100, the edges nearby the sharp corner are too close, and thus the problem of light concentration of sharp starbursts is prone to occurring. In these embodiments of the present application, the plurality of segments 602 are connected with a smooth transition, and it is unlikely to form a sharp corner at the connection between two adjacent segments 602, and thus the display effect of the display panel 10 can be improved.

In an embodiment, when the orthographic projection of the filter portion 610 on the substrate 100 is enclosed by the plurality of arc-shaped segments 601 connected in sequence, as shown in FIG. 7, the bending directions of two adjacent arc-shaped segments 601 may be opposite, that is, the two adjacent arc-shaped segments 601 may be connected with a smooth transition to better alleviate the problem of the sharp starbursts. In one embodiment, as shown in FIG. 8, the bending directions of two adjacent arc-shaped segments 601 are the same. When two adjacent arc-shaped segments 601 are both bent toward the center of an orthographic projection of the light shielding portion 620 on the substrate 100, it can be considered that the bending directions of the two adjacent arc-shaped segments 601 are the same; and when one of two adjacent arc-shaped segments 601 is bent toward the center of the orthographic projection of the light shielding portion 620 on the substrate 100, and the other is bent away from the center of the orthographic projection, it can be considered that the bending directions of the two adjacent arc-shaped segments 601 are different.

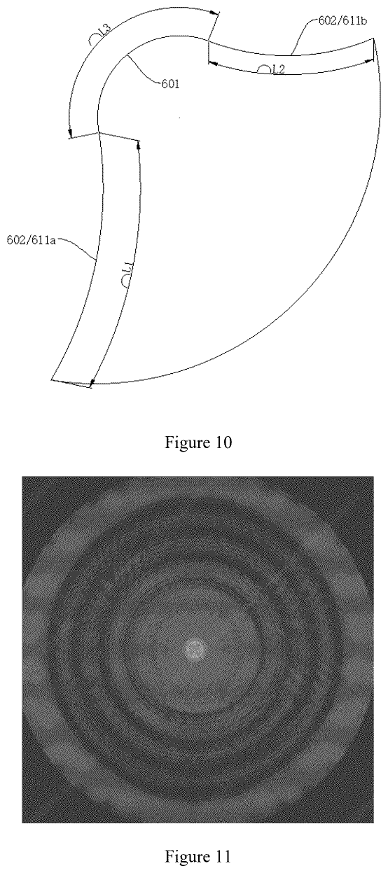

In an embodiment, when two adjacent segments 602 are connected with a smooth transition by means of an arc-shaped segment 601, the two segments 602 connected with a smooth transition by means of the arc-shaped segment 601 may be shaped in a variety of ways. For example, as shown in FIG. 9, at least one segment 602 may be straight. In one embodiment, as shown in FIG. 10, the two segments 602 connected with a smooth transition by means of an arc-shaped segment 601 are arc-shaped, that is, the orthographic projection of the filter portion 610 on the substrate 100 is further enclosed by a plurality of arc-shaped segments 601 connected in sequence.

By two adjacent segments 602 being connected with a smooth transition by means of an arc-shaped segment 601, it is meant that there is no sharp corner at the connections between the two segments 602 and the arc-shaped segment 601 between the two segments. When the segments 602 are straight, the segments 602 are tangent to the arc-shaped segment 601 connected to the segments; and when the segments 602 are arc-shaped, tangent lines of the segments 602 coincide with tangent lines of the arc-shaped segment 601 connected to the segments at the connections.

Three sides L1, L2 and L3 of the orthographic projection of the same filter portion 610 on the substrate 100 may be configured in a variety of ways. As shown in FIG. 8, the three sides L1, L2 and L3 are all bent toward a filter area A1, and the three sides L1, L2 and L3 are all arc-shaped segments 601. As shown in FIG. 9, among the three sides L1, L2 and L3, the side L3 is straight, the side L1 and the side L2 are arc-shaped, and the side L3 and the side L2 are connected with a smooth transition by means of a further arc-shaped segment 601 L4, and the side L3 and the side L1 are connected with a smooth transition by means of a further arc-shaped segment 601 L5. In one embodiment, as shown in FIG. 10, the three sides L1, L2 and L3 are all arc-shaped and are connected to each other with a smooth transition.

In some embodiments of the present application, as shown in FIG. 10, two adjacent segments 602 are both arc-shaped and are connected with a smooth transition by means of an arc-shaped segment 601, that is, the edge of the orthographic projection of the filter portion 610 on the substrate 100 includes only arc-shaped segments 601, and the arc-shaped segments 601 are connected with a smooth transition. Among the three arc-shaped segments 601 connected to each other, the bending directions of the arc-shaped segments 601 on two sides may be the same, while the bending direction of the middle arc-shaped segment 601 is opposite to the bending direction of the arc-shaped segments 601 on the two sides, and the three arc-shaped segments 601 connected to each other can be connected with a smooth transition.

In some embodiments, with continued reference to FIGS. 5 to 10, the plurality of filter portions 610 include a first filter portion 611. A plurality of first filter portion 611 are provided. The first filter portion 611 includes the filter area A1 and a diffusion area A2 located on a circumferential side of the filter area A1. The orthographic projection of the pixel opening 320 on the substrate 100 is located within an orthographic projection of the filter area A1 on the substrate 100, and the diffusion area A2 extends from the filter area A1 toward other filter portions 610 adjacent to the first filter portion 611.

In these embodiments, the first filter portion 611 includes the filter area A1 and the diffusion area A2; and the filter area A1 is positioned correspondingly to the pixel opening 320, so that the filter area A1 can have a filtering effect. The diffusion area A2 extends from the filter area A1 toward other filter portions 610, and the diffusion area A2 may cover part of a surface of the light shielding portion 620 to reduce the amount of the light reflected from the light shielding portion 620, thereby improving the light output effect of the display panel 10.

In an embodiment, the filter area A1 may be considered as a part of the first filter portion 611 located in the light shielding opening 630, and the diffusion area A2 may be considered as a part extending beyond the corresponding filter opening. The filter area A1 and the diffusion area A2 are configured as an integral structure, in other words, the filter area and the diffusion area are formed integrally, the filter area A1 and the diffusion area A2 are parts of the first filter portion 611 located in different areas, and there is no physical structural boundary between the filter area A1 and the diffusion area A2.

In an embodiment, with reference to FIGS. 5 and 7, an orthographic projection of the diffusion area A2 on the substrate 100 has a first side 611a and a second side 611b. The first side 611a is located on a side of the first filter portion 611 facing one of the filter portions 610, the second side 611b is located on a side of the first filter portion 611 facing the other filter portion 610, and the first side 611a and the second side 611b are connected with a smooth transition to alleviate the above problem of sharp starbursts occurring when a sharp corner is formed between the first side 611a and the second side 611b. The first side 611a and the second side 611b being connected with a smooth transition may be the first side 611a and the second side 611b being connected with a smooth transition by means of another arc-shaped segment located therebetween. For example, the plurality of segments 602 include the first side 611a and the second side 611b, and the first side 611a and the second side 611b are connected with a smooth transition by means of an arc-shaped segment 601, so that the problem of sharp starbursts can be alleviated. In some other embodiments, the first side 611a and the second side 611b being connected with a smooth transition may also be the first side 611a and the second side 611b being directly connected with a smooth transition. For example, the first side 611a and the second side 611b are arc-shaped, that is, the first side 611a and the second side 611b are both the arc-shaped segments 601 as described above and are connected with a smooth transition.

The first side 611a and the second side 611b may be shaped in a variety of ways. The first side 611a and/or the second side 611b may be straight. In some other embodiments, the first side 611a and the second side 611b are arc-shaped, that is, the first side 611a and the second side 611b are both arc-shaped segments 601 as described above, to further improve the light output effect of the display panel 10.

In an embodiment, the orthographic projection of each pixel opening 320 on the substrate 100 is circular or elliptical, and correspondingly the orthographic projection of each filter opening on the substrate 100 is circular or elliptical to ensure the display effect. Thus, orthographic projections of other light shielding portions 620, apart from the light shielding portion 620, on the substrate 100 are circular or elliptical, and in order to adapt to the shapes of the other light shielding portions 620, the first side 611a and the second side 611b are arc-shaped to increase the distribution area of the diffusion area A2 to the greatest extent. When the first side 611a and the second side 611b face different light shielding portions 620, in order to allow the first side 611a and the second side 611b to adapt to the different light shielding portions 620, intermediate positions of the first side 611a and the second side 611b are both bent toward the filter area A1, the bending directions of the first side 611a and the second side 611b are the same, the first side 611a and the second side 611b are connected to each other by means of an arc-shaped segment 601, and the arc-shaped segment 601 connected to the first side 611a and the second side 611b may be bent in a direction away from the filter area A1. In one embodiment, the first side 611a is connected with a smooth transition to the arc-shaped segment 601, and the second side 611b is also connected with a smooth transition to the arc-shaped segment 601.

In an embodiment, the plurality of filter portions 610 further include second filter portions 612 and third filter portions 613. A plurality of second filter portions 612 and a plurality of third filter portions 613 are provided. The plurality of second filter portions 612 and the plurality of third filter portions 613 are alternately distributed on the circumferential side of the first filter portion 611. The first side 611a may be located on a side of the first filter portion 611 facing the second filter portion 612, and the second side 611b may be located on a side of the first filter portion 611 facing the third filter portion 613.

In an embodiment, at least part of the diffusion area A2 is located between two adjacent other filter portions 610 to increase the distribution area of the diffusion area A2, thereby better decreasing the amount of reflected light.

For example, when the plurality of filter portions 610 include the second filter portions 612 and the third filter portions 613, the diffusion area A2 extends toward the third filter portion 613 and passes between two adjacent second light shielding portions 620, and at least part of the diffusion area A2 may be located between the two adjacent second filter portions 612 to shorten distances between the diffusion area A2 and other light shielding portions 620 and increase the distribution area of the first filter portion 611, thereby better decreasing the amount of reflected light.

In an embodiment, four second filter portions 612 and four third filter portions 613 are alternately distributed on the circumferential side of the same first filter portion 611, as shown in FIG. 7. The diffusion area A2 includes four first diffusion sub-areas A21 surrounding the filter area A1. Each first diffusion sub-area A21 extends from the filter area A1 toward the third filter portion 613, and a part of each first diffusion sub-area A21 is located between two adjacent second filter portions 612.

In these embodiments, the first filter portion 611 is substantially in the shape of a cross, the first filter portion 611 includes the filter area A1 and the four first diffusion sub-areas A21 located on the circumferential side of the filter area A1, and the four diffusion areas A2 extend respectively toward the four third filter portions 613, so that the distribution area of the first filter portion 611 can be further enlarged.

In an embodiment, the diffusion area A2 may further include a second diffusion sub-area A22. The second diffusion sub-area A22 extends from the filter area A1 toward the second filter portion 612. In an embodiment, the diffusion area A2 on a side of the first side 611a facing the filter area A1 is the second diffusion sub-area A21, and the diffusion area A2 on a side of the second side 611b facing the filter area A1 is the first diffusion sub-area A21. The boundaries between the first diffusion sub-areas A21 and the second diffusion sub-areas A22 are delineated with dashed lines in FIG. 7, and the dashed lines do not limit the structure of the display panel of the present application.

In an embodiment, the first sides 611a of the diffusion area A2 respectively face the corresponding second filter portions 612, and each diffusion area A2 includes second sides 611b each connected between two first sides 611a, the second side 611b being located on the side of the first filter portion 611 facing the third filter portion 613, and the first filter portion 611 can be shaped to further adapt to the shapes of the second filter portion 612 and the third filter portion 613. Each of the first side 611a and the second side 611b may be arc-shaped, that is, each of the first side 611a and the second side 611b may be an arc-shaped segment 601, and each first side 611a and the respective second side 611b are connected with a smooth transition by means of an arc-shaped segment 601, and the edge of the orthographic projection of the first filter portion 611 is enclosed by the plurality of arc-shaped segments 601 connected end to end, and two adjacent segments 602 are also connected with a smooth transition to better improve the light output effect of the display panel 10.

The first filter portion 611, the second filter portion 612 and the third filter portion 613 may be configured in a variety of ways. For example, the first filter portion 611 is a red filter portion 610, the second filter portion 612 is a green filter portion 610, and the third filter portion 613 is a blue filter portion 610. Since human eyes are more sensitive to green, the first filter portion 611 being a red filter portion 610 can alleviate the problem of greenish display of the display panel 10, and thus the use effect of the display panel 10 is improved.

In an embodiment, the light-emitting units 330 include a first light-emitting unit 331, a second light-emitting unit 332 and a third light-emitting unit 333. The first light-emitting unit 331 may be configured to emit red light, the second light-emitting unit 332 may be configured to emit green light, and the third light-emitting unit 333 may be configured to emit blue light. In an embodiment, the pixel openings 320 include a first pixel opening 321 for receiving the first light-emitting unit 331, a second pixel opening 322 for receiving the second light-emitting unit 332, and a third pixel opening 323 for receiving the third light-emitting unit 333. In an embodiment, the light shielding openings 630 include a first light shielding opening 631, a second light shielding opening 632 and a third light shielding opening 633. The first light shielding opening 631 is positioned correspondingly to the first pixel opening 321, that is, an orthographic projection of the first pixel opening 321 on the substrate 100 is located within an orthographic projection of the first light shielding opening 631 on the substrate 100, the second light shielding opening 632 is positioned correspondingly to the second pixel opening 322, and the third light shielding opening 633 is positioned correspondingly to the third pixel opening 323.

The first light-emitting unit 331, the second light-emitting unit 332 and the third light-emitting unit 333 may be configured in a variety of ways. For example, the first light-emitting unit 331 is located at a first vertex of a first virtual polygon T, the third light-emitting unit 333 is located at a second vertex of the first virtual polygon T, and the first vertex and the second vertex are alternately spaced apart from each other in a first direction X or a second direction Y. The first virtual polygon is a trapezoid. For example, the first virtual polygon T includes an upper base and a lower base which are parallel to each other and extend in the second direction Y, and the first light-emitting unit 331 and the third light-emitting unit 333 are respectively located at two ends of each of the upper base and the lower base, and the first light-emitting unit 331 and the third light-emitting unit 333 can be alternately distributed at intervals in the second direction.

In an embodiment, every two of the first direction X, the second direction Y and the thickness direction Z of the display panel intersect with each other. For example, every two of the first direction X, the second direction Y and the thickness direction Z of the display panel are perpendicular to each other. In an embodiment, both the first direction X and the second direction Y are parallel to the light exit surface.

In an embodiment, the second light-emitting unit 332 is located inside the first virtual polygon T, allowing two first light-emitting units 331 and two third light-emitting units 333 to be alternately arranged on a circumferential side of the second light-emitting unit 332.

From another perspective, it may also be considered that the third light-emitting units 333 are located at four vertices of a second virtual polygon, the second light-emitting units 332 are located on four sides of the second virtual polygon, and the first light-emitting unit 331 is located inside the second virtual polygon. The second virtual polygon is a quadrangle.

The arrangement of the first filter opening, the second filter opening and the third filter opening is the same as the arrangement of the first light-emitting unit 331, the second light-emitting unit 332 and the third light-emitting unit 333, which will not be described in detail herein. The arrangement of the first pixel opening 321, the second pixel opening 322 and the third pixel opening 323 adapts to the arrangement of the first light-emitting unit 331, the second light-emitting unit 332 and the third light-emitting unit 333, which will not be described in detail herein.

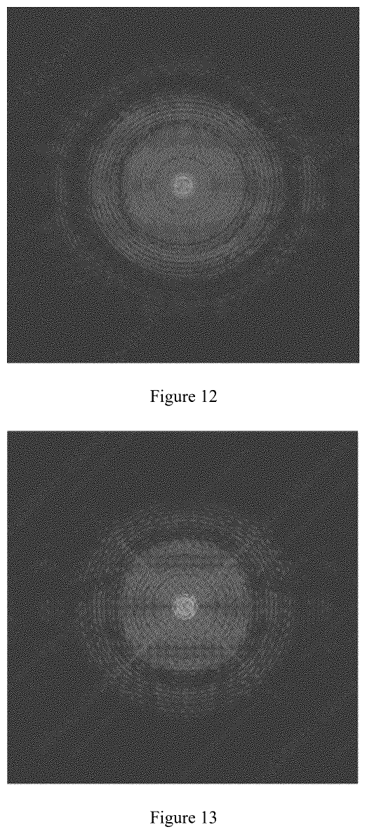

As shown in FIG. 11, FIG. 11 is a structural schematic view of a display panel of the related art in an active state, and FIG. 11 illustrates a schematic view showing partial light emission of one of sub-pixels and a circumferential side thereof. The inventors have found that there is a pronounced circular diffraction ring on the circumferential side of the sub-pixel of the conventional display panel, that is, there is one or more bright circular rings surrounding the light-emitting unit 330. As shown in FIG. 12, FIG. 12 is a schematic view illustrating the luminous effect of one of the light-emitting units 330 of the display panel according to an embodiment of the present application. By improving an inclination angle of the inner wall surface 301, more light reflected from the inner wall surface 301 exits in the forward direction, the amount of the light reflected at a large angle from the inner wall surface 301 decreases, the circular diffraction ring existing on the circumferential side of the light-emitting unit 330 can be effectively alleviated, and the light output effect of the display panel 10 can be improved.

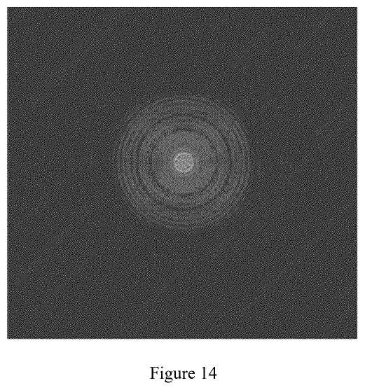

Further, as shown in FIG. 13, FIG. 13 is a structural schematic view of a display panel of the related art in an active state, and FIG. 13 illustrates a schematic view showing partial light emission of one of sub-pixels and a circumferential side thereof. The inventors have found that when there is a sharp corner at an edge of the filter portion corresponding to the sub-pixel of the conventional display panel, a pronounced circular diffraction ring exists in the active state thereof, the luminance of the circular diffraction ring is nonuniform, starbursts exist, and the inventors have found that the starbursts are caused by the presence of a sharp corner area at the edge of the orthographic projection of the filter portion 610 on the substrate 100. In the embodiments of the present application, the edge of the orthographic projection of the filter portion 610 on the substrate 100 is formed by connecting the plurality of arc-shaped segments 601 to each other, and adjacent arc-shaped segments 601 are connected with a smooth transition, so that excessively high local luminance can be alleviated properly, and the problem of the starbursts affecting the display effect during display is avoided. Reference is made to FIG. 14 for specific details.

As shown in FIGS. 1 to 10, an embodiment of a first aspect of the present application further provides a display panel 10, including a substrate 100 and a pixel defining layer 300. The pixel defining layer 300 includes a pixel defining portion 310 and pixel openings 320 enclosed by the pixel defining portion 310. A plurality of pixel openings 320 are provided. The pixel defining portion 310 includes an inner wall surface 301 facing at least one of the pixel openings 320, a cross section of the inner wall surface 301 in the thickness direction Z includes a curve segment, and an included angle between the curve segment and a light exit surface of the display panel 10 ranges from 25° to 35°. In an embodiment, the included angle between the curve segment and the light exit surface of the display panel 10 may be an included angle between a tangent line of the curve segment and the light exit surface.

In the embodiments of the present application, the first electrode 210, the second electrode 410 and the filter layer 600 as described above may further be included. In an embodiment, the configuration of the pixel defining layer 300 in the embodiment of the present application is as described above and will not be described in detail herein.

As described above, light is reflected by the first electrode 210 and then reaches and reflected by the inner wall surface 301. When the included angle between the curve segment and the thickness direction Z is excessively large, the inner wall surface 301 is excessively flat, and the light reflected from the inner wall surface 301 has a relatively large exit angle and it is prone to forming a circular diffraction ring on the circumferential side of the pixel opening 320, affecting the display effect of the display panel 10. While when the included angle between the curve segment and the thickness direction Z is excessively small, the inner wall surface 301 is excessively inclined, it is unlikely to fill, with the encapsulation layer 500, a pit formed at the location of the pixel opening 320, resulting in that the filter portion 610 may be arranged on an uneven surface, and thus affecting the filtering effect of the filter portion 610. In the embodiments of the present application, when the included angle between the arc curve segment and the light exit surface is in the above range, the circular diffraction ring formed due to the excessively flat inner wall surface 301 can be alleviated, the filtering effect of the filter portion 610 can also be ensured, the display effect of the display panel 10 is thus ensured, and the use performance of the display panel 10 is improved.

In an embodiment, the cross section of the inner wall surface 301 in the thickness direction may include an arc segment 302, that is, the curve segment includes an arc segment 302. The included angle between a tangent line of the arc segment 302 and the thickness direction ranges from 25° to 35°.

In some other embodiments, the cross section of the inner wall surface 301 in the thickness direction includes a plurality of arc segments 302 connected in sequence in the direction away from the substrate 100, an included angle between each arc segment 302 and the thickness direction ranging from 25° to 35°, that is, the curved segment includes a plurality of arc segments 302 connected in sequence in the direction away from the substrate 100.

For the relevant description of the arc segments 302, reference may be made to the relevant description in the above embodiments, which will not be described in detail herein.

In these embodiments, the curve segment includes the plurality of arc segments 302, and by adjusting the positions and angles of the plurality of arc segments 302, the circular diffraction ring can be alleviated, and the effect of the filter portion 610 can also be ensured. For example, in the direction away from the substrate 100, an included angle between the previous arc segment 302 and the light exit surface is greater than the included angle between the subsequent arc segment 302 and the light exit surface, that is, the closer to the substrate 100, the greater the degree of inclination of the arc segment 302, the smaller the included angle between the reflected light of the arc segment 302 and the thickness direction, and the better the circular diffraction ring can be alleviated. The farther away from the substrate 100, the flatter the arc segment 302, the better the degree of evenness of a surface of the encapsulation layer 500 facing away from the substrate 100, and the better the filtering effect of the filter portion 610 can be improved, thereby improving the overall light output effect of the display panel 10.

In one embodiment, the included angle between each arc segment 302 and the light exit surface is in a value range of 27° to 33° to better improve the overall display effect of the display panel 10. For example, the value of the included angle between the tangent line of each arc segment 302 and the light exit surface is 25°, 25.5°, 26°, 26.2°, 27°, 28°, 29°, 32°, 33°, 34.8°, 35°, etc.

As shown in FIGS. 1 to 10, an embodiment of the first aspect of the present application further provides a display panel 10. The display panel 10 includes a substrate 100, a pixel defining layer 300 and a filter layer 600. The pixel defining layer 300 is arranged on the substrate 100, the pixel defining layer 300 includes a pixel defining portion 310 and pixel openings 320 enclosed by the pixel defining portion 310. A plurality of pixel openings 320 are provided. The filter layer 600 is located on a side of the pixel defining layer 300 facing away from the substrate 100, and the filter layer 600 includes a plurality of filter portions 610. An edge of an orthographic projection of at least one of the filter portions 610 on the substrate 100 is enclosed by a plurality of arc-shaped segments 601 connected in sequence.

In the display panel 10 according to the embodiment of the present application, the edge of the orthographic projection of the filter portion 610 on the substrate 100 is enclosed by the plurality of arc-shaped segments 601, so that the shape of the edge of the orthographic projection of the filter portion 610 on the substrate 100 is made smoother, it is unlikely to form a sharp corner area outside the edge of the filter portion 610, thus making it unlikely for the light to be diffracted significantly in the sharp corner area of the filter portion 610, and the light output effect of the display panel 10 can be improved.

The configuration of the filter layer 600 is as described above and will not be described in detail herein. For example, the filter layer 600 includes the light shielding portion 620 and the light shielding opening 630 enclosed by the light shielding portion 620 as described above.

The configuration of the plurality of filter portions 610 is as described above and will not be described in detail herein. For example, the filter portion 610 includes the first filter portion 611, the second filter portion 612 and the third filter portion 613 as described above. The first filter portion 611 includes the filter area A1 and the diffusion area A2 as described above. The arrangement of the first filter portion 611, the second filter portion 612 and the third filter portion 613 is as described above.

In an embodiment, in the embodiments of the present application, the pixel defining portion 310 includes the inner wall surface 301 facing at least one of the pixel openings 320, and the configuration of the inner wall surface 301 is as described above and will not be described in detail herein.

As shown in FIGS. 1 to 10, an embodiment of the first aspect of the present application further provides a display panel 10, including a substrate 100, a pixel defining layer 300 and a filter layer 600. The pixel defining layer 300 is arranged on the substrate 100, and the pixel defining layer 300 includes a pixel defining portion 310 and a pixel opening 320. The filter layer 600 is located on a side of the pixel defining layer 300 facing away from the substrate 100, and the filter layer 600 includes a plurality of filter portions 610. An edge of an orthographic projection of the filter portion 610 on the substrate 100 includes a plurality of segments 602, two adjacent segments 602 being connected with a smooth transition by means of an arc-shaped segment 601.

As described above, when there is a sharp corner at the edge of the orthographic projection of the filter portion 610, the edges nearby the sharp corner are too close, resulting in light concentration, and thus the display problem of sharp starburst occurs. In the embodiment of the present application, the plurality of segments 602 are connected with a smooth transition, and it is unlikely to form a sharp corner at the connection between two adjacent segments 602, and the display problem of sharp starbursts can be alleviated.

The configurations of the pixel defining layer 300 and the filter layer 600 are as described above and will not be described in detail herein. Any two embodiments of the present application may be referenced interchangeably.

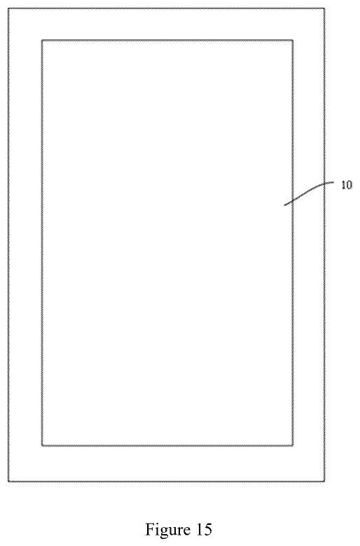

An embodiment of a second aspect of the present application further provides a display device, as shown in FIG. 15, including a display panel 10 according to any one of the above embodiments of the first aspect. Since the display device according to the embodiment of the second aspect of the present application includes the display panel 10 of any one of the above embodiments of the first aspect, the display device according to the embodiment of the second aspect of the present application has the beneficial effects of the display panel 10 of any one of the above embodiments of the first aspect, and will not be described in detail here.

The display device in the embodiment of the present application includes, but is not limited to devices having a display function, such as a cell phone, a personal digital assistant (PDA), a tablet computer, an e-book, a television, an access control, a smart fixed-line telephone, or a control console.

Although the present application is described with reference to the embodiments, various modifications can be made, and equivalents can be provided to substitute for the components thereof without departing from the scope of the present application. In particular, the embodiments can be combined in any manner, provided that there is no structural conflict. The present application is not limited to the specific embodiments disclosed herein but includes all the embodiments that fall within the scope of the claims.

1. A display panel, comprising:
a substrate; and
a pixel defining layer arranged on the substrate, the pixel defining layer comprising a pixel defining portion and a plurality of pixel openings enclosed by the pixel defining portion,
wherein the pixel defining portion comprises an inner wall surface facing at least one of the pixel openings, a cross section of the inner wall surface in a thickness direction of the display panel comprises a plurality of arc segments sequentially connected to each other in a direction away from the substrate, and among at least two adjacent arc segments, an included angle between the arc segment closer to the substrate and a light exit surface of the display panel is greater than an included angle between the arc segment farther from the substrate and the light exit surface of the display panel; and the included angle between the arc segment and the light exit surface of the display panel opens toward the corresponding pixel defining portion.

2. The display panel according to claim 1, wherein the included angle between each arc segment and the light exit surface of the display panel is in a value range of 25° to 35°.

3. The display panel according to claim 1, wherein among any two adjacent arc segments of the plurality of arc segments, an included angle between the arc segment closer to the substrate and the light exit surface of the display panel is greater than an included angle between the arc segment farther from the substrate and the light exit surface of the display panel.

4. The display panel according to claim 1, wherein each of the arc segments is in the shape of a circular arc;
or the pixel defining portion has the inner wall surface facing each of the pixel openings.

5. The display panel according to claim 1, further comprising: a filter layer located on a side of the pixel defining layer facing away from the substrate, the filter layer comprising a plurality of filter portions, wherein an edge of an orthographic projection of at least one of the filter portions on the substrate comprises one or more arc-shaped segments.

6. The display panel according to claim 5, the filter layer further comprises a light shielding portion and a light shielding opening formed at the light shielding portion, at least part of the filter portion being located at the light shielding opening;
an orthographic projection of the light shielding opening on the substrate is located within the orthographic projection of the filter portion on the substrate; and
part of the filter portion is located on a side of the light shielding portion facing away from the substrate.

7. The display panel according to claim 5, wherein the edge of the orthographic projection of the filter portion on the substrate is enclosed by the one or more arc-shaped segments that are connected in sequence, or
the edge of the orthographic projection of the filter portion on the substrate comprises a plurality of segments, two adjacent segments being connected by the arc-shaped segment.

8. The display panel according to claim 5, wherein the plurality of filter portions comprise a first filter portion, the first filter portion comprising a filter area and a diffusion area located on a circumferential side of the filter area, wherein an orthographic projection of the pixel opening on the substrate is located within an orthographic projection of the filter area on the substrate, and the diffusion area extends from the filter area toward other filter portion adjacent to the first filter portion.

9. The display panel according to claim 8, wherein an orthographic projection of the diffusion area on the substrate has a first side and a second side; the first side is located on a side of the first filter portion facing one of the filter portions; and the second side is located on a side of the first filter portion facing the other of the filter portions, and the first side and the second side are connected.

10. The display panel according to claim 8, wherein a first side and a second side are arc-shaped segments, or the first side and the second side are connected by the arc-shaped segment.

11. The display panel according to claim 9, wherein the plurality of filter portions further comprise a plurality of second filter portions and a plurality of third filter portions; the plurality of second filter portions and the plurality of third filter portions are alternately distributed on a circumferential side of the first filter portion; and
the first side is located on a side of the first filter portion facing the second filter portion, and the second side is located on a side of the first filter portion facing the third filter portion.

12. The display panel according to claim 11, wherein an orthographic projection of the second filter portion on the substrate is circular or elliptical, and an orthographic projection of the third filter portion on the substrate is circular or elliptical; and
the first side and the second side are recessed toward the corresponding filter area, the arc-shaped segment is connected between the first side and the second side, and the arc-shaped segment protrudes in a direction away from the filter area.

13. The display panel according to claim 12, wherein at least part of the diffusion area of the first filter portion is located between two adjacent other filter portions; and
at least part of the diffusion area is located between two adjacent second filter portions.

14. The display panel according to claim 13, wherein four second filter portions and four third filter portions are alternately distributed on the circumferential side of the first filter portion; the diffusion area comprises four first diffusion sub-areas surrounding the filter area, each first diffusion sub-area extending from the filter area toward the third filter portion, and at least part of each first diffusion sub-area being located between two adjacent second filter portions; and
the first filter portion is a red filter portion, the second filter portion is a green filter portion, and the third filter portion is a blue filter portion.

15. A display panel, comprising:
a substrate; and
a filter layer, located on one side of the substrate, the filter layer comprising a plurality of filter portions, an edge of an orthographic projection of at least one filter portion on the substrate being enclosed by a plurality of arc-shaped segments connected in sequence.

16. The display panel according to claim 15, wherein the filter layer further comprises a light shielding portion and a light shielding opening formed at the light shielding portion, at least part of the filter portion being located at the light shielding opening; and
an orthographic projection of the light shielding opening on the substrate is located within the orthographic projection of the filter portion on the substrate.

17. The display panel according to claim 15, wherein the plurality of filter portions comprise a first filter portion, the first filter portion comprising a filter area and a diffusion area located on a circumferential side of the filter area, the diffusion area extending from the filter area toward other filter portion adjacent to the first filter portion.

18. The display panel according to claim 17, wherein an orthographic projection of the diffusion area on the substrate has a first side and a second side, wherein the first side is located on a side of the first filter portion facing one of the filter portions, the second side is located on a side of the first filter portion facing the other of the filter portions, the first side and the second side are arc-shaped, and the first side and the second side are connected.

19. A display panel, comprising:
a substrate; and
a filter layer, located on one side of the substrate, the filter layer comprising a plurality of filter portions, wherein an edge of an orthographic projection of at least one of the filter portions on the substrate comprises a plurality of segments, two adjacent segments being connected by an arc-shaped segment.

20. The display panel according to claim 19, wherein the segment is arc-shaped.
